(19) United States
(12) Patent Application Publication
(10) Pub. No.: US 2012/0314391 A1
(43) Pub. Date: Dec. 13, 2012

(54) CIRCUIT BOARD AND METHOD FOR MAKING THE SAME

(75) Inventors: TSUNG-SHENG HUANG, Tu-Cheng (TW); CHUN-JEN CHEN, Tu-Cheng (TW); DUEN-YI HO, Tu-Cheng (TW); WEI-CHIEH CHOU, Tu-Cheng (TW)

(73) Assignee: HON HAI PRECISION INDUSTRY CO., LTD., Tu-Cheng (TW)

(21) Appl. No.: 13/183,452

(22) Filed: Jul. 15, 2011

(30) Foreign Application Priority Data
Jun. 10, 2011 (TW) 100120476

(51) Int. Cl. H05K 7/12; H05K 7/00

(52) U.S. Cl. 361/767; 361/760

(57) ABSTRACT

A circuit board includes a base board defining a number of via holes, a power supply connection unit, a load connection unit, and at least one capacitor connection unit(s). Each of the at least one capacitor connection unit(s) includes two capacitor connectors, and one of the two capacitor connectors is positioned nearer to the power supply connection unit and farther away from the load connection unit than the other. The via holes are divided into at least one group(s) corresponding to each of the capacitor connection unit(s), and all of the via holes in each of the group(s) are equidistantly positioned along a semicircle arc surrounding the capacitor connector of the capacitor connection unit corresponding to the group that is positioned nearer to the power supply connection unit.

### BACKGROUND

1. Technical Field

The present disclosure relates to circuit boards, and particularly to a circuit board that is capable of using filter capacitors more effectively and a method for making the same.

2. Description of Related Art

When power is supplied to a load, a change of current passing through the load may generate voltage ripples, and these voltage ripples may adversely affect the stability of the voltage supplied to the load by the power supply circuit. Therefore, filter capacitors are often used for filtering these voltage ripples. However, when the filter capacitors are installed on circuit boards, the interaction of via holes defined in the circuit boards and the filter capacitors fitted in them may generate inductance. The effects of this inductance may increase the impedances of the circuit boards and adversely affect the effectiveness of the filter capacitors.

Therefore, there is room for improvement within the art.

### BRIEF DESCRIPTION OF THE DRAWINGS

Many aspects of the present disclosure can be better understood with reference to the following drawings. The components in the various drawings are not necessarily drawn to scale, the emphasis instead being placed upon clearly illustrating the principles of the present disclosure. Moreover, in the drawings, like reference numerals designate corresponding parts throughout the figures.

FIG. 1 is a schematic view of a circuit board, according to a first exemplary embodiment.

FIG. 2 is a schematic view of a circuit board, according to a second exemplary embodiment.

FIG. 3 is a schematic view of a circuit board, according to a third exemplary embodiment.

FIG. 4 is a diagram that shows the relationship between resonance frequencies and the impedances of capacitors respectively connected to a number of circuit boards including the circuit boards shown in FIG. 1 and FIG. 2 and FIG. 3.

### DETAILED DESCRIPTION

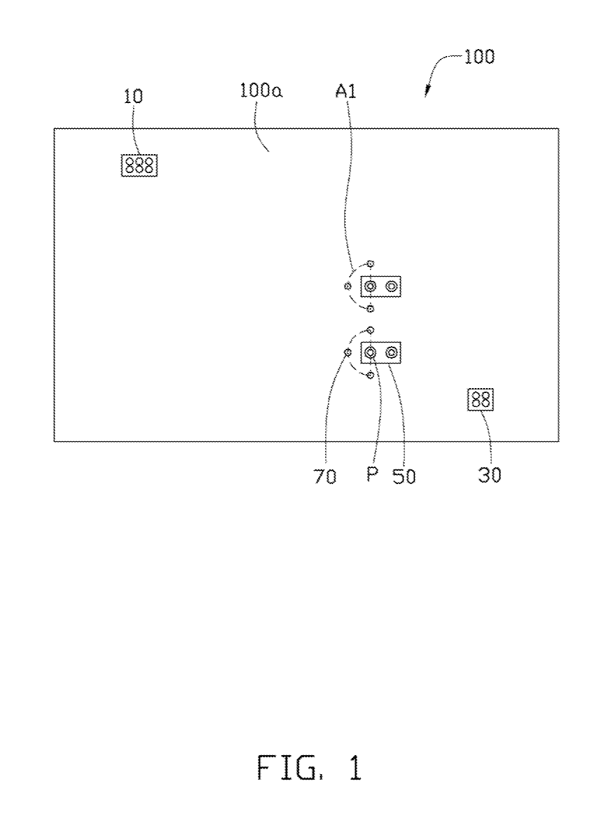

FIG. 1 is a schematic view of a circuit board 100, according to a first exemplary embodiment. The circuit board 100 includes a base board 100a, a power supply connection unit 10, a load connection unit 30, at least one capacitor connection unit 50 (the present disclosure shows two, but it should be understood that more than two capacitor connections can be used in substantially the same manner). The base board 100a defines a number of via holes 70 therein.

The base board 100a can be a typical circuit board. The power supply connection unit 10, the load connection unit 30, and the capacitor connection unit(s) 50 are all mounted on the base board 100a. In particular, all of the power supply connection unit 10, the load connection unit 30, and the capacitor connection unit(s) 50 can be groups of electrically conductive pads formed on the base board 100a. The capacitor connection unit(s) 50 is/are connected to both the power supply connection unit 10 and the load connection unit 30 through the base board 100a. In use, typical power supplies (not shown), loads (not shown), and filter capacitors (not shown) can be appropriately connected to the power supply connection unit 10, the load connection unit 30, and the capacitor connection unit(s) 50, by such means as would be known to those of ordinary skill in the art. Thus, the power supplies can supply electric power of different levels to the loads through the base board 100a and the filter capacitors, and the filter capacitors can filter and cancel any voltage ripples generated, such that the loads may receive a stable voltage(s).

Each of the least one capacitor connection unit(s) 50 includes two capacitor connectors P, which can be electrically conductive pads. The two capacitor connectors P may be connected in series through the base board 100a, that is to say orientated or aligned so as to place one of the connectors P nearer to and connected to the power supply connection unit 10, and the other connector P closer to and connected to the load connection unit 30. The capacitor connector P positioned nearer to the power supply connection unit 10 is connected to the power supply connection unit 10 through the base board 100a, and the capacitor connector P positioned nearer to the load connection unit 30 is connected to the load connection unit 30 through the base board 100a. Thus, current coming from the power supplies connected to the power supply connection unit 10 can enter the capacitor connection unit 50 through the capacitor connector P positioned nearer to the power supply connection unit 10, pass through the capacitor connection 50, and be further transmitted to the load connection unit 30 through the capacitor connector P positioned nearer to the load connection unit 30. In this way, the filter capacitors connected to the capacitor connection unit 50 can filter the voltage ripples generated in the process of supplying electric power to the loads when the current passes through the capacitor connection unit 50.

The via holes 70 are used to connect different conductive layers (not shown) of the base board 100a to or through each other, by such means as would be known to those of ordinary skill in the art. The structure of each of the via holes 70 can be similar to that of typical via holes. In this embodiment, the base board 100a defines six via holes 70, and the via holes 70 are divided into two groups suitable for the two capacitor connection units 50. Each of the two groups includes three via holes 70. In each of the two groups, the three via holes 70 are equidistantly positioned along a semicircle of a certain radius (semicircle arc A1). The semicircle arc A1 surrounds a capacitor connector P of the capacitor connection unit 50 corresponding to the group that is positioned nearer to the power supply connection unit 10. Two of the three via holes 70 are diametrically opposite each other within the semicircle arc A1, such that the two via holes 70 and the capacitor connector P of the capacitor connection unit 50 corresponding to the group that is positioned nearer to the power supply connection unit 10 are co-linear. Furthermore, the two via holes 70 respectively positioned at the two ends of the semicircle arc A1 are equidistant to the capacitor connector P of the capacitor connection unit 50 corresponding to the group that is positioned nearer to the load connection unit 30.

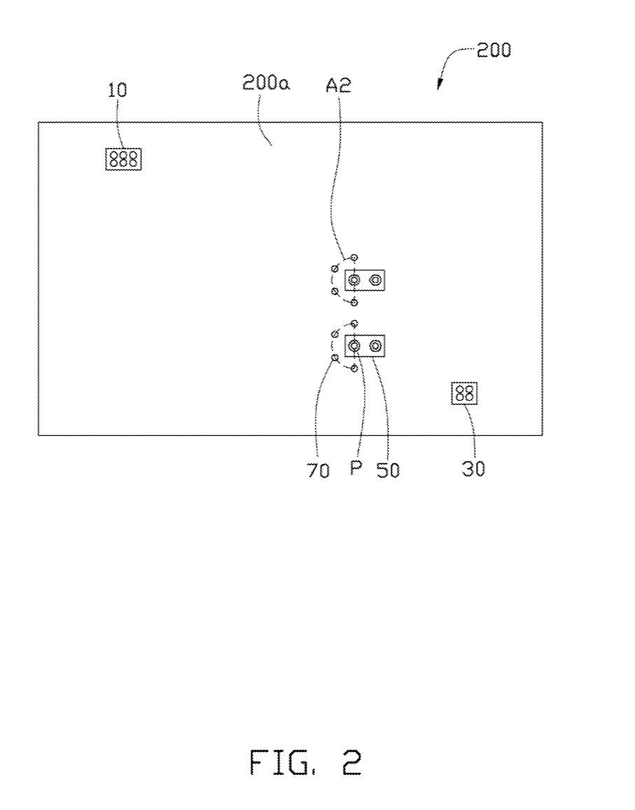

FIG. 2 is a schematic view of a circuit board 200, according to a second exemplary embodiment. The circuit board 200 differs from the circuit board 100 in that a base board 200a replaces the base board 100a. The base board 200a differs from the base board 100a in that the base board 200a defines more via holes 70 than the base board 100a. In this embodiment, the base board 200a defines eight via holes 70, and the via holes 70 are divided into two groups respectively corresponding to the two capacitor connection units 50. Each of the two groups includes four via holes 70. In each of the two groups, the four via holes 70 are equidistantly positioned along a semicircle of a certain radius (semicircle arc A2). The semicircle arc A2 surrounds a capacitor connector P of the capacitor connection unit 50 corresponding to the group that is positioned nearer to the power supply connection unit 10. Two of the four via holes 70 are diametrically opposite each other within the semicircle arc A2, such that the two via holes 70 and the capacitor connector P of the capacitor connection unit 50 corresponding to the group that is positioned nearer to the power supply connection unit 10 are co-linear. Furthermore, the two via holes 70 respectively positioned at the two ends of the semicircle arc A2 are equidistant to the capacitor connector P of the capacitor connection unit 50 corresponding to the group that is positioned nearer to the load connection unit 30.

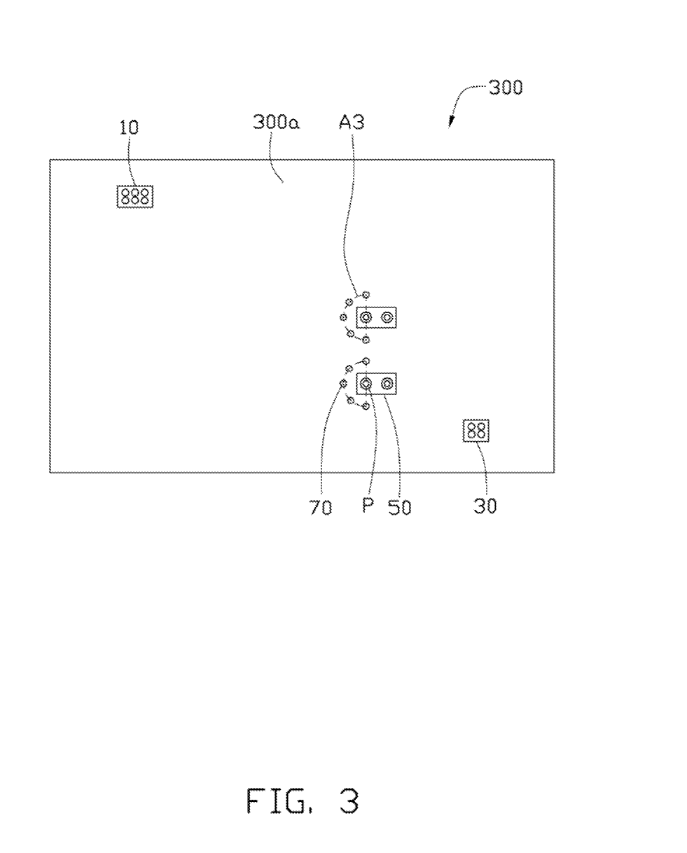

FIG. 3 is a schematic view of a circuit board 300, according to a third exemplary embodiment. The circuit board 300 differs from the circuit board 100 in that a base board 300a replaces the base board 100a. The base board 300a differs from the base board 100a only in that the base board 300a defines more via holes 70 than the base board 100a. In this embodiment, the base board 300a defines ten via holes 70, and the via holes 70 are divided into two groups respectively corresponding to the two capacitor connection units 50. Each of the two groups includes five via holes 70. In each of the two groups, the five via holes 70 are equidistantly positioned along a semicircle of a certain radius (semicircle arc A3). The semicircle arc A3 surrounds the capacitor connector P of the capacitor connection unit 50 corresponding to the group that is positioned nearer to the power supply connection unit 10. Two of the five via holes 70 are diametrically opposite each other within the semicircle arc A3, such that the two via holes 70 and the capacitor connector P of the capacitor connection unit 50 corresponding to the group that is positioned nearer to the power supply connection unit 10 are co-linear. Furthermore, the two via holes 70 respectively positioned at the two ends of the semicircle arc A3 are equidistant to the capacitor connector P of the capacitor connection unit 50 corresponding to the group that is positioned nearer to the load connection unit 30.

Furthermore, the circuit boards 100, 200, and 300 can include more capacitor connection units 50 and defines more via holes 70, provided that all of the via holes 70 are divided into a number of groups corresponding to each of the capacitor connection units 50, and all of the via holes 70 in each of the groups are positioned in the manner suggested by the first, second and third exemplary embodiments.

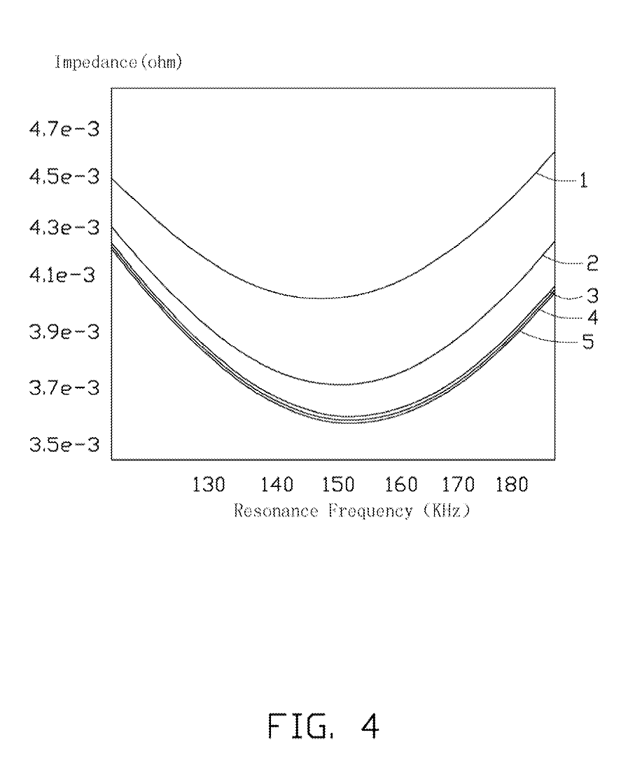

FIG. 4 is a diagram that describes the relationship between the resonance frequencies and the impedances of capacitors connected to the capacitor connection units 50. In particular, curve 1 shows the relationship between resonance frequencies and the impedances of a filter capacitor connected to an aforementioned capacitor connection unit 50, wherein no via hole 70 is positioned adjacent to the capacitor connection unit 50. Curve 2 shows the relationship between resonance frequencies and the impedances of a filter capacitor connected to an aforementioned capacitor connection unit 50, wherein at least one via hole 70 is positioned adjacent to the capacitor connection unit 50, but at positions dissimilar to those of the via holes 70 of the circuit boards 100, 200 and 300. Curve 3 shows the relationship between resonance frequencies and the impedances of a filter capacitor connected to either of the capacitor connection units 50 of the circuit board 100. Curve 4 shows the relationship between resonance frequencies and the impedances of a filter capacitor connected to either of the capacitor connection units 50 of the circuit board 200. Curve 5 shows the relationship between resonance frequencies and the impedances of a filter capacitor connected to either of the capacitor connection units 50 of the circuit board 300.

As shown in FIG. 4, at the same resonance frequencies, the filter capacitor connected to the capacitor connection unit 50 without any via hole 70 positioned adjacent thereto has the highest impedance, and is unable to filter most of the voltage ripples. The filter capacitor connected to the capacitor connection unit 50 with at least one via hole 70 positioned adjacent thereto but at positions dissimilar to those of the via holes 70 of the circuit boards 100, 200 and 300 has less impedance, but the impedance may be not low enough to ensure effective filtration for the voltage ripples. The filter capacitors connected to the capacitor connection units 50 of the circuit boards 100, 200, and 300 have similar impedances, all of which are lower than either that of the filter capacitor connected to the capacitor connection unit 50 without any adjacent via hole 70, or the filter capacitor connected to the capacitor connection unit 50 with at least one via hole 70 positioned adjacent thereto but at positions dissimilar to those of the via holes 70 of the circuit boards 100, 200 and 300. Thus, the filter capacitors connected to the capacitor connection units 50 of the circuit boards 100, 200, and 300 can more effectively filter the voltage ripples.

In the present disclosure, the filter capacitors can be connected to the circuit boards 100, 200, and 300 to filter voltage ripples. According to the methods for positioning the via holes 70 as defined for the circuit boards 100, 200, and 300, the impedances of the filter capacitors connected to the circuit boards 100, 200, and 300 can be decreased, and the filter capacitors connected to the circuit boards 100, 200, and 300 can effectively filter the voltage ripples generated in the processes of supplying electric power to the loads through the circuit boards 100, 200, and 300.

A method for making the circuit board 100/200/300 can include these steps: providing the base board 100a/200a/300a; forming the power supply connection unit 10, the load connection unit 30, and the capacitor connection unit(s) 50 on the base board 100a/200a/300a; defining the via holes 70 in the base board 100a/200a/300a, wherein the via holes 70 are positioned according to the methods detailed above; and connecting the power supply connection unit 10 to the load connection unit 30 through the base board 100a/200a/300a and the capacitor connection unit(s) 50.

It is to be further understood that even though numerous characteristics and advantages of the present embodiments have been set forth in the foregoing description, together with details of structures and functions of various embodiments, the disclosure is illustrative only, and changes may be made in detail, especially in matters of shape, size, and arrangement of parts within the principles of the present invention to the full extent indicated by the broad general meaning of the terms in which the appended claims are expressed.

What is claimed is:

1. A circuit board, comprising:
a base board defining a number of via holes;
a power supply connection unit mounted on the base board;
a load connection unit mounted on the base board; and
at least one capacitor connection unit(s) mounted on the base board, each of the at least one capacitor connection unit(s) including two capacitor connectors, one of the two capacitor connectors positioned nearer to the power supply connection unit and farther away from the load connection unit than the other of the two capacitor connectors; wherein the via holes are divided into at least one group(s) corresponding to each of the capacitor connection unit(s), and all of the via holes in each of the group(s) are equidistantly positioned along a semicircle arc surrounding the capacitor connector of the capacitor connection unit corresponding to the group that is positioned nearer to the power supply connection unit.

2. The circuit board as claimed in claim 1, wherein two of the via holes in each of the group(s) are diametrically opposite each other within the semicircle arc, such that the two via holes and the capacitor connector are co-linear.

3. The circuit board as claimed in claim 2, wherein the two via holes respectively positioned at the two ends of the semicircle arc are equidistant to the capacitor connector of the capacitor connection unit corresponding to the group that is positioned nearer to the load connection unit.

4. The circuit board as claimed in claim 1, wherein the power supply connection unit, the load connection unit, and the capacitor connection unit(s) are all conductive pad groups formed on the base board.

5. The circuit board as claimed in claim 1, wherein the capacitor connector of each of the at least one capacitor connection unit(s) that is positioned nearer to the power supply connection unit is connected to the power supply connection unit through the base board, and the capacitor connector of each of the at least one capacitor connection unit(s) that is positioned nearer to the load connection unit is connected to the load connection unit through the base board.

6. The circuit board as claimed in claim 1, wherein when a power supply, a load, and at least one filter capacitor(s) are respectively connected to the power supply connection unit, the load connection unit, and the at least one capacitor connection unit(s), the power supply supplies electric power to the load through the base board and the filter capacitor(s), and the filter capacitor(s) filter voltage ripples generated in the power supplying process.

7. A method for making a circuit board, comprising:
providing a base board;
comprising a power supply connection unit, a load connection unit, and at least one capacitor connection unit(s) on the base board, wherein each of the at least one capacitor connection unit(s) includes two capacitor connectors, one of the two capacitor connectors positioned nearer to the power supply connection unit and farther away from the load connection unit than the other of the two capacitor connectors;
defining a number of via holes in the base board, wherein the via holes are divided into at least one group(s) corresponding to each of the capacitor connection unit(s), and all of the via holes in each of the group(s) equidistantly positioned along a semicircle arc surrounding the capacitor connector of the capacitor connection unit corresponding to the group that is positioned nearer to the power supply connection unit; and
connecting the power supply connection unit to the load connection unit through the base board and the at least one capacitor connection unit(s).

8. The method as claimed in claim 7, further comprising:
positioning two of the via holes in each of the group(s) to be diametrically opposite each other within the semicircle arc, such that the two via holes and the capacitor connector are co-linear.

9. The method as claimed in claim 8, further comprising:
positioning the two via holes respectively positioned at the two ends of the semicircle arc to be equidistant to the capacitor connector of the capacitor connection unit corresponding to the group that is positioned nearer to the load connection unit.

10. The method as claimed in claim 7, wherein the power supply connection unit, the load connection unit, and the capacitor connection unit(s) are all conductive pad groups formed on the base board.

11. The method as claimed in claim 7, further comprising:
connecting the capacitor connector of each of the at least one capacitor connection unit(s) that is positioned nearer to the power supply connection unit to the power supply connection unit through the base board, and connecting the capacitor connector of each of the at least one capacitor connection unit(s) that is positioned nearer to the load connection unit to the load connection unit through the base board.
